(19) United States
(12) Patent Application Publication
(10) Pub. No.: US 2003/0168334 A1
(43) Pub. Date: Sep. 11, 2003

(54) High temperature shape memory alloy thin film

(75) Inventors: Gregory K. Rasmussen, Grand Blanc, MI (US); Jinping Zhang, Grand Blanc, MI (US); Fenglian Chang, Grand Blanc, MI (US); Terry J. Gold, Davidson, MI (US)

Correspondence Address: PATRICK M. GRIFFIN, DELPHI TECHNOLOGIES, INC., Legal Staff, Mail Code: 480-414-420, P.O. Box 5052, Troy, MI, 48007-5052, US

(73) Assignee: DELPHI TECHNOLOGIES, INC., TROY, MI

(21) Appl. No.: 09/882,217

(22) Filed: Jun. 15, 2001

(51) Int. Cl. C23C 14/32

(52) U.S. Cl. 204/192.15

(57) ABSTRACT

A magnetron sputter deposition process for producing a thin film alloy exhibiting shape memory characteristics comprising conducting the sputter deposition using krypton as process gas, depositing the alloy onto heated substrate so secondary annealing is unnecessary, and using a sputter target titanium, nickel and/or palladium in proportions so as to produce a thin film alloy of a composition having a titanium content ranging from at least about 50 atomic percent to less than about 52 atomic percent.

### TECHNICAL FIELD

This invention relates to a method of producing shape-memory alloy films by sputtering process techniques. In particular, it relates to a method of producing high temperature shape-memory nickel titanium palladium films.

### BACKGROUND OF THE INVENTION

Various metallic materials capable of exhibiting shape-memory characteristics are well known in the art. These shape-memory capabilities occur as the result of the metallic alloy undergoing a reversible crystalline phase transformation from one crystalline state to another crystalline state with a change in temperature and/or external stress. In particular, it was discovered that alloys of nickel and titanium exhibited these remarkable properties of being able to undergo energetic crystalline phase changes at ambient temperatures, thus giving them a shape-memory. These alloys, if plastically deformed while cool, will revert, exerting considerable force, to their original, undeformed shape when warmed. These energetic phase transformation properties render articles made from these alloys highly useful in a variety of applications. An article made of an alloy having a shape memory can be deformed at a low temperature from its original configuration, but the article “remembers” its original shape, and returns to that shape when heated.

For example, in nickel titanium alloys possessing shape-memory characteristics, the alloy undergoes a reversible transformation from an austenitic state to a martensitic state with a change in temperature. This transformation is often referred to as a thermoelastic martensitic transformation.

The reversible transformation of the NiTi alloy between the austenite to the martensite phases occurs over two different temperature ranges which are characteristic of the specific alloy. As the alloy cools, it reaches a temperature (Mₛ) at which the martensite phase starts to form, and finishes the transformation at a still lower temperature (M_{f}). Upon reheating, it reaches a temperature (Aₛ) at which austenite begins to reform and then a temperature (A_{f}) at which the change back to austenite is complete. In the martensitic state, the alloy can be easily deformed. When sufficient heat is applied to the deformed alloy, it reverts back to the austenitic state, and returns to its original configuration.

Shape-memory materials previously have been produced in bulk form, in the shape of wires, rods, and plates, for utilities such as pipe couplings, electrical connectors, switches, and actuators, and the like. Actuators previously have been developed, incorporating shape-memory alloys or materials, which operate on the principal of deforming the shape-memory alloy while it is below its phase transformation temperature range and then heating it to above its transformation temperature range to recover all or part of the deformation, and, in the process of doing so, create moments of one or more mechanical elements. These actuators utilize one or more shape-memory elements produced in bulk form, and, therefore are limited in size and usefulness.

The unique properties of shape-memory alloys further have been adapted to applications such as micro-actuators by means of thin film technology. Micro-actuators are desirable for such utilities as opening and closing valves, activating switches, and generally providing motion for micro-mechanical devices. It is reported that the advantageous performance of micro-actuators is attributed to the fact that the shape-memory effect of the stress and strain can produce substantial work per unit of volume. For example, the work output of nickel-titanium shape-memory alloy is of the order of 1 joule per gram per cycle. A shape-memory film micro-actuator measuring one square millimeter and ten microns thick is estimated to exert about 64 microjoules of work per cycle.

The most well known and most readily available shape-memory alloy is an alloy of nickel and titanium. With a temperature change of as little as about 10° C., this alloy can exert a force of as much as 415 MPa when applied against a resistance to changing its shape fiom its deformation state.

Although numerous potential applications for shape-memory alloys now require materials featuring phase transformation temperatures above about 100° C., the martensite start point for the common commercially available nickel-titanium alloys barely exceeds about 80° C. In order to meet higher temperature applications, ternary alloys have been investigated, using various additional metallic elements. For example, substitution of noble metals (Au, Pd, Pt) for Ni in NiTi alloys successfully accomplishes higher temperature phase transformations, but, poor workability and diminished mechanical properties make these alloys less than attractive, and the costs introduced are somewhat prohibitive for many commercial applications Ternary nickel-titanium shape-memory alloys including a zirconium or hafnium component appear to be potentially economical high temperature shape-memory candidates. However, such ternary nickel-titanium shape-memory alloys including zirconium or hafnium exhibit intrinsically larger hysteresis which prolongs phase transformation response times, making these alloys less favorable in some applications.

### BRIEF DESCRIPTION OF THE DRAWINGS

The above discussed and other features and advantages of the present invention will be appreciated and understood by those skilled in the art from the following detailed description and drawings, wherein like elements are designated by like numerals in the several figures.

Referring now to the drawings:

FIG. 1 shows a typical tensile stress-strain curve of a NiTiPd thin film made by using Krypton as the working gas, pursuant to the present invention.

FIG. 2 shows a tensile stress-strain curve of a NiTiPd thin film made by using Argon as the working gas.

FIG. 3 depicts the recoverable strain versus temperature curve of the produced NiTiPd according to the present invention.

FIG. 4 depicts a DSC curve of the produced NiTiPd film according to the present invention.

### SUMMARY OF THE INVENTION

One of the most widely practiced applications for shape memory alloys is in the field of actuation. Because the activation of actuators made of shape memory alloys is accomplished by altering the temperature of the alloy through phase transformation, the particular characteristic transformation temperature of the alloys basically limits the specific environment where articles made from that alloy can practically be employed. Alloys with a martensitic transformation temperature higher than 100° C. are almost essential for actuator applications in automotive and aerospace devices. A number of potential alloys have been studied, with the most preferred alloys being the pseudo-binary alloys containing Ni, Ti, and the third element Pd or Hf, where Pd is intended to substitute for Ni, and Hf to substitute for Ti in order to form near equiatomic compositions. Between these preferred Ni—Ti—Hf and Ni—Ti—Pd alloys, one of the most distinguishing differences is the transformational hysteresis. It is noted that Ni—Ti—Hf alloys usually have a transformational hysteresis of about 60° C., while Ni—Ti—Pd alloys typically have a hysteresis of about 20° C. to 30° C. In applications associated with cyclic actuation by Joule heating, a smaller hysteresis is very desireable, since this property accommodates faster response time. Accordingly, Ni—Ti—Pd alloys are the particularly preferred alloys for such high temperature actuator applications.

Characteristics of heat dissipation of the SMA articles also is an important criteria for an actuator alloy because the material needs to be cooled down to martensitic transformation temperature before deformation can be effected. Favorable decreasing of response time may be accomplished by thickness reduction of the SMA articles, which serves to expedite the heat dissipation of the article. Hence, using shape memory alloy in the form of thin ribbon or thin film becomes highly desirable; minimizing the amount of noble metal-containing NiTiPd SMA also makes such parts more cost effective and practical. However, the poor workability of NiTiPd alloy has prohibited the manufacture of NiTiPd ribbons. In addition, although the fabrication of thin film NiTiPd alloy has been reported, the mechanical properties of these alloys has not been good enough to make durable parts.

Now, accordingly to the present invention, a magnetron sputter deposition process has been developed for producing a thin film alloy exhibiting shape memory characteristics comprising conducting the sputter deposition using a krypton process gas, and using a sputter target comprising components selected from nickel, titanium, and palladium in proportions so as to produce a thin film alloy having a composition having a titanium content ranging from at least about 50 atomic percent to less than about 52 atomic percent. Preferably, the alloy produced is a Ti₅₀₋₅₂(NiPd)₄₈₋₅₀ alloy wherein the proportion of palladium ranges from at least about 10 at % to about 50 at. % of the alloy content, more preferably from about 20 at % to about 40 at % of the alloy content.

Preferably, the target used in the sputter deposition is a hot pressed powder target. In addition, it is preferred to conduct the deposition employing a hot substrate, i.e. in-situ deposition and annealing, so as to produce thin film that has shape memory effect and requires no separate annealing process.

### DESCRIPTION OF AN EMBODIMENT OF THE INVENTION

In a sputtering process, as in the present invention, the sputtering deposition generally takes place in a chamber, such as a Perkin Elmer chamber. The particular process parameters for sputtering deposition are dependent on the specific sputtering equipment employed. An initial base vacuum pressure first is established; this pressure ranges from about 2×10⁻⁶ torr or lower. Preferably, the base vacuum pressure ranges from about 5×10⁻⁷ torr or lower. Power applied during sputtering for an 8″ diameter target should range between about 300 watts to about 6 kilowatts (power density with respect to target size from about 9.2 kW/m² to 185 kW/m²); preferably the power applied ranges from about 500 watts to about 3 kilowatts (power density 15.4 kW/m² to 92.5 kW/m²).

During the ion sputtering process, ionization process gas should be maintained at a pressure ranging from about 0.5 to about 5.0 mTorr.

Preferably, process gas pressure ranges from about 0.5 mTorr to about 2.0 mTorr. The ionizing process gas utilized in the present invention is krypton, rather than a conventional process gas such as argon. The use of krypton accomplishes production of thin alloy film with high mechanical strength and good ductility. Using the present process, films can be produced featuring fracture stress greater than about 800 MPa up to about 1.2 GPa, shape recoverable strain greater than about 2.0% up to about 3.0%, hysteresis less than about 40 degrees C. to as little as about 15 degrees C., and ductility at room temperature greater than 6.0% up to about 10%.

Thin alloy SMA films having a range of NiTiPd compositions and thicknesses can be deposited using the present process. Preferred shape memory alloy thin film compositions are alloys featuring compositions in the range: (NiPd)₄₈₋₅₀Ti₅₀₋₅₂. Film thickness ranging from about 1.5 micron to about 10 microns are preferred; particularly preferred are deposited film thicknesses ranging from about 3 microns to about 5 microns. It is preferred to deposit the sputtered film onto a hot substrate to produce in-situ a thin alloy film having shape memory effect. In this manner, a separate annealing process is not required. Typical substrate materials include glass, silicon, silicon nitride, and the like. A silicon substrate with oxide layer is preferred. The substrate is maintained at a temperature ranging from about 300° C. to about 500° C. during deposition; a substrate temperature ranging from about 400° C. to about 450° C. is preferred.

Pursuant to the present process, hot pressed metal targets having an elemental composition close to that of the desired alloy film to be deposited are utilized, based on the empirical results of composition shift between deposited film and the target. These targets can be fabricated by conventional hot pressing method which includes first mixing metallic powders in the desired proportions together, blending the powder mixture and degassing, putting the blend into target mold, and consolidating the blend by applying heating and pressure at the same time.

The following examples are provided to further describe the invention. The examples are intended to be illustrative and are not to be construed as limiting the scope of the invention.

### EXAMPLE 1

8″-diameter targets with different NiTiPd compositions were prepared by hot pressing method. Based on the empirical composition shift between thin film and target, compositions of the targets were selected in order to make slightly Ti rich films. Hot pressing was accomplished by standard procedure and the final density of the target was measured to determine fraction of porosity. Table A shows the composition of a typical produced target that was used for this study, the theoretical and measured density, and the fraction of porosity calculated accordingly. To protect targets from oxygen contamination, they were sealed in Ar until ready to be put into vacuum chamber.

TABLE A
Target composition, final density and calculated porosity.

| Target Composition | Theoretical density | Measured density | Porosity |
|---|---|---|---|
| (atomic percent) | (g/cc) | (g/cc) | (%) |
| Ti_{53.5}Pd_{24.5}Ni₂₂ | 6.9 | 6.5 | 5.8 |

NiTiPd films with different compositions were sputter deposited on 5″-diameter oxide passivated hot Si substrates (420° C.) from the hot pressed targets. Deposition parameters included: base pressure 5×10⁻⁷ torr before deposition, working gas Ar pressure 10 mTorr during deposition, target-to-substrate distance 3.3 inches, deposition power 1.0 kW, substrate temperature 400° C. and deposition time 50 minutes. The thickness of the thin film deposited was about 4.5 82 m. Chemical composition of the film around wafer center was measured by x-ray Energy Dispersive Spectrum (EDS) equipped on a Scanning Electron Microscope (SEM), and the transformation temperatures were measured by Differential Scanning Calorimetry (DSC). NiTiPd composition of a film deposited across a 4″ area in the center of a substrate is reported in Table B. below. The composition and the transition temperatures of film deposited from two different targets are shown in Table C.

TABLE B
NiTiPd Film Composition and Deviation σ Across a 4″ Area

| | Ti | | Ni | | Pd | |
|---|---|---|---|---|---|---|
| | (at %) | (σ) | (at %) | (σ) | (at %) | (σ) |
| Center | 50.62 | (0.2) | 24.98 | (0.21) | 24.41 | (0.25) |
| 0.5″ from | 50.80 | (0.2) | 24.94 | (0.21) | 24.26 | (0.25) |
| center | | | | | | |
| 1″ from center | 50.87 | (0.21) | 25.02 | (0.22) | 24.11 | (0.25) |
| 1.5″ from | 51.00 | (0.21) | 24.98 | (0.22) | 24.02 | (0.25) |
| center | | | | | | |
| Edge | 51.49 | (0.21) | 25.08 | (0.24) | 23.43 | (0.25) |

TABLE C
Composition and Transition Temperatures of Films Sputtered From
Different Targets.

| target atomic | film atomic | Mₛ | M_{f} | Aₛ | A_{f} |
|---|---|---|---|---|---|
| composition | composition | (° C.) | (° C.) | (° C.) | (° C.) |
| Ti_{53.5}Pd_{24.5}Ni22 | Ti_{51.1}Pd_{26.9}Ni₂₂ | 156 | 140 | 162 | 185 |
| Ti_{53.5}Pd_{24.5}Ni22* | Ti_{50.6}Pd_{24.4}Ni₂₅ | 153 | 142 | 158 | 172 |

*target was modified by inserting nickel rods near the wear track.

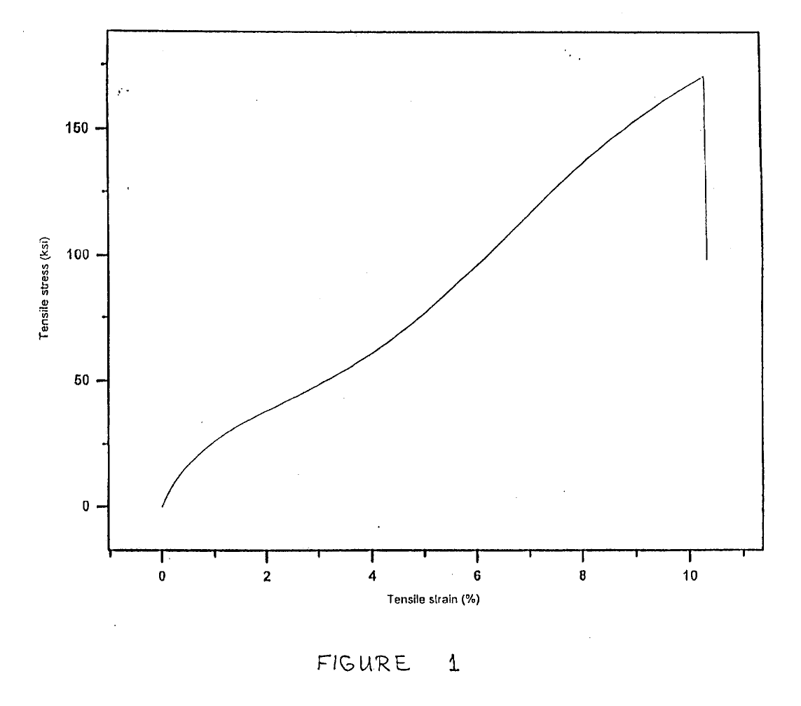

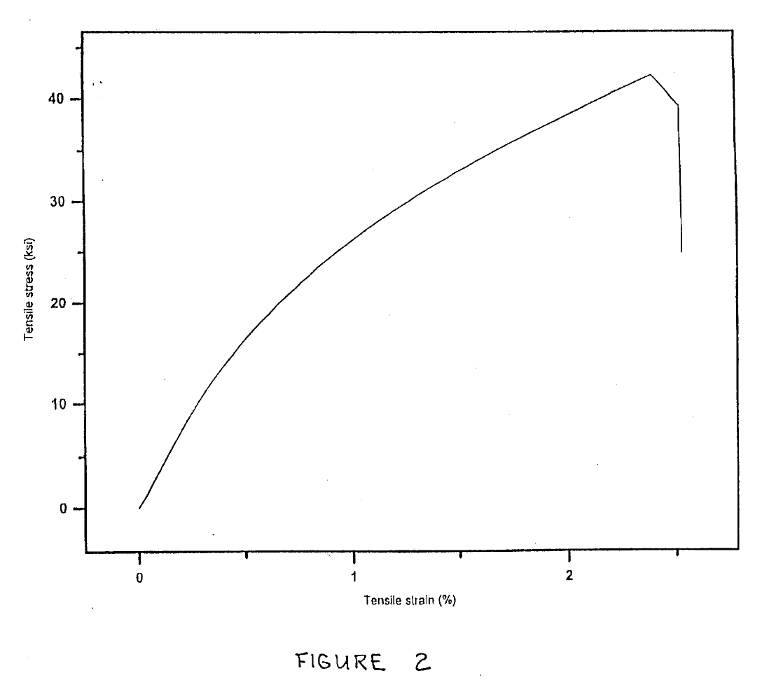

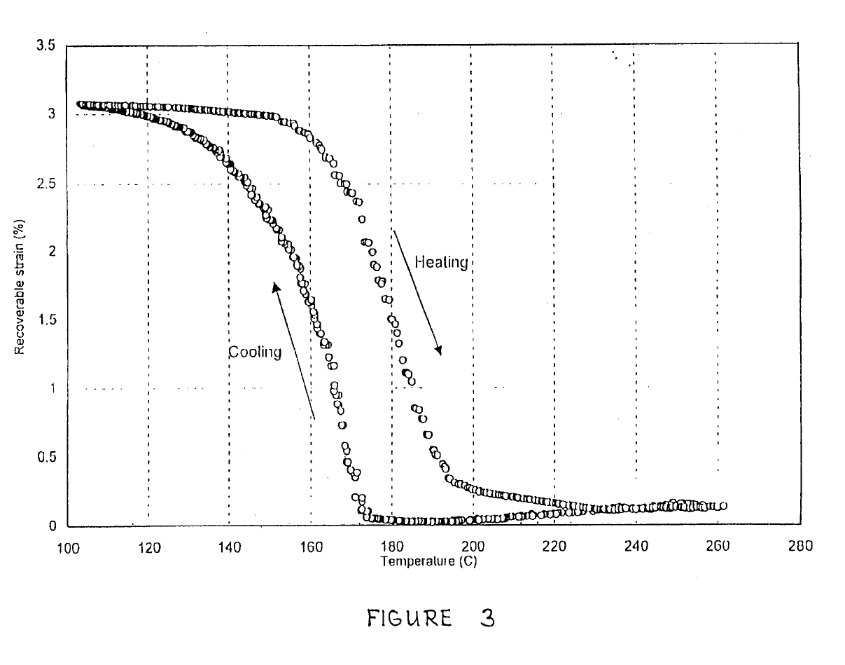

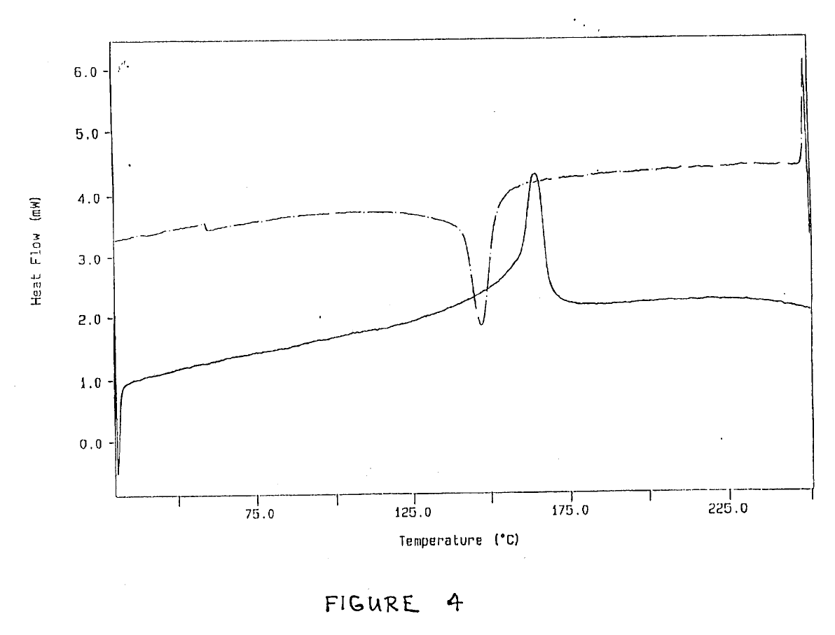

Mechanical and shape-memory properties of the deposits were evaluated by tensile testing at room temperature and thermal cycling under constant load. Thin film was deposited by the procedure described previously, and then was mechanically delaminated from the substrate and cut to 3 mm×30 mm dimension. At strain rate of ˜0.08/min, the fracture strength was close to 1200 MPa. Thermal cycling was conducted under constant load at different stress levels with temperature from 100° C. and 250° C. It was found the maximum sustainable stress for thermal cycling was close to 1000 MPa. Strain-temperature hysteresis loop was observed during stressed thermal cycling, and the recoverable strain was up to 3.0%. FIG. 1 shows a typical tensile stress-strain curve of a NiTiPd thin film made by using krypton as the working gas. As a comparison to FIG. 1, FIG. 2 shows a tensile stress-strain curve of a NiTiPd thin film produced by by using argon as the working gas. The recoverable strain versus temperature curve of the produced Ti_{50.6}Pd_{24.4}Ni₂₅ film is depicted in FIG. 3. A DSC curve of the produced Ti_{50.6}Pd_{24.4}Ni₂₅ film is depicted in FIG. 4, illustrating a hysteresis about 20°.

Various other embodiments or other modifications of the disclosed embodiments will be apparent to those skilled in the art upon reference to this description, or may be made without departing from the spirit and scope of the invention defined in the appended claims.

We claim:

1. A magnetron sputter deposition process for producing a thin film alloy exhibiting shape memory characteristics comprising:
conducting the deposition using krypton as process gas; and,
using a sputter target comprising components selected from the group consisting of nickel, titanium, and palladium in proportions so as to produce a thin film alloy of a composition having a titanium content ranging from at least about 50 atomic percent to less than about 52 atomic percent.

2. The process of claim 1 wherein said sputter target is a hot pressed powder target.

3. The process of claim 1 comprising heating a substrate onto which the thin film alloy is deposited to maintain a temperature ranging from about 300° C. to about 500° C. during said deposition.

4. The process of claim 4 comprising heating a substrate onto which the thin film alloy is deposited to maintain a temperature ranging from about 400° C. to about 450° C. during said deposition.

5. The process of claim 1 comprising forming a deposited thin film alloy having a thickness ranging from about 1.5 microns to about 10 microns.

6. The process of claim 5 comprising forming a deposited thin film alloy having a thickness ranging from about 3 microns to about 5 microns.

7. The process of claim 1 comprising using a sputter target so as to produce a Ti₅₀₋₅₂(NiPd)₄₈₋₅₀ alloy.

8. The process of claim 7 comprising using a sputter target so as to produce a Ti₅₀₋₅₂(NiPd)₄₈₋₅₀ alloy wherein the proportion of palladium ranges from at least about 10 at % to about 50 at. % of the alloy content

9. The process of claim 8 comprising using a sputter target so as to produce a Ti₅₀₋₅₂(NiPd)₄₈₋₅₀ alloy wherein the proportion of palladium ranges from at least about 20 at % to about 40 at. % of the alloy content.

10. A magnetron sputter deposition process for producing a thin film alloy exhibiting shape memory characteristics comprising:
conducting the deposition using krypton as process gas;
heating a substrate onto which the thin film alloy is deposited to maintain a temperature ranging from about 300° C. to about 500° C. during said deposition;
using a hot pressed powder sputter target comprising components selected from the group consisting of nickel, titanium, and palladium in proportions so as to produce a thin film alloy of a composition having a titanium content ranging from at least about 50 atomic percent to less than about 52 atomic percent; and,
forming a deposited thin film alloy having a thickness ranging from about 1.5 microns to about 10 microns

11. A magnetron sputter deposition process for producing a thin film alloy exhibiting shape memory characteristics comprising:
conducting the deposition using krypton as process gas;
heating a substrate onto which the thin film alloy is deposited to maintain a temperature ranging from about 300° C. to about 500° C. during said deposition;
using a hot pressed powder sputter target comprising components selected from the group consisting of nickel, titanium, and palladium in proportions so as to produce a thin film Ti₅₀₋₅₂(NiPd)₄₈₋₅₀ alloy wherein the proportion of palladium ranges from at least about 10 at % to about 50 at. % of the alloy content; and,
forming a deposited thin film alloy having a thickness ranging from about 1.5 microns to about 10 microns.
